(19) United States
(12) Patent Application Publication
(10) Pub. No.: US 2016/0278220 A1
(43) Pub. Date: Sep. 22, 2016

(54) DISPLAY DEVICE

(71) Applicants: BOE Technology Group Co., Ltd., Beijing (CN); Beijing BOE Multimedia Technology Co., Ltd., Beijing (CN)

(72) Inventors: Huijun LI, Beijing (CN); Jigang LV, Beijing (CN); Xinhua JIA, Beijing (CN); Yansheng SUN, Beijing (CN)

(21) Appl. No.: 14/778,439

(22) PCT Filed: Mar. 31, 2015
(86) PCT No.: PCT/CN2015/075493

§ 371 Date: Sep. 18, 2015

(30) Foreign Application Priority Data
Oct. 28, 2014 (CN) 201420632262.5

(51) Int. Cl. H05K 5/02; H05K 5/00

(52) U.S. Cl. CPC H05K 5/02; H05K 5/0017

(57) ABSTRACT

A display device comprises a back plate and an outer frame disposed around the back plate, wherein one of the outer frame and the back plate is provided with a magnetic member and the other is provided with an absorption member for magnetically absorbing the corresponding magnetic member, and the outer frame and the back plate are fixedly connected by the magnetic absorption between the magnetic member and the absorption member.

### BACKGROUND OF THE INVENTION

1. Field of the Invention

The present disclosure relates to a display field, in particular, to a display device which is convenient for assembly.

2. Description of the Related Art

In the prior art, as shown in FIG. 1, after a display device is installed and assembled, a screw hole is in advance provided on an outer frame 1 thereof, and a screw head hole is in advance provided on a back plate thereof. The back plate is installed into the outer frame 1 and is fixed by a screw 2. Such installation has the disadvantage that since the screw 2 is visible from the outside, the product appearance is adversely affected, and also the installation procedures are tedious and waste time and energy.

### SUMMARY OF THE INVENTION

One of objectives of the present invention is to provide a display device, in order to improve installing efficiency of the display device.

In accordance with one aspect of the present invention, it provides a display device, comprising a back plate and an outer frame disposed around the back plate, wherein one of the outer frame and the back plate is provided with a magnetic member and the other is provided with an absorption member for magnetically absorbing the corresponding magnetic member, and the outer frame and the back plate are fixedly connected by the magnetic absorption between the magnetic member and the absorption member.

In the above embodiment, since the structure is connected by the magnetic absorption which is located between the outer frame and the back plate, it facilitates the installation of the outer frame. Specifically, upon installing, the magnetic absorption between the outer frame and the back plate can fixedly connect the outer frame with the back plate rapidly, thereby finishing the installation of the entire display device. This facilitates the installation of the entire display device; meanwhile, the display device 10 is neat and decent on appearance.

Preferably, a positioning step structure is provided on the outer frame to cooperate with the back plate, thereby facilitating the positioning thereof upon installing.

Preferably, the magnetic member comprises a plurality of first magnetic strips and the absorption fixation between the outer frame and the back plate is achieved by the cooperation of the first magnetic strips and the absorption member.

Preferably, any two adjacent first magnetic strips of the plurality of first magnetic strips have opposite polarities in the direction towards the back plate, thereby avoiding forming the magnetic field having too strong magnetism.

Alternatively, the magnetic member is provided on the side of the outer frame toward the back plate and the absorption member is provided on the side of the back plate toward the outer frame; or the magnetic member is provided on the side of the back plate toward the outer frame and the absorption member is provided on the side of the outer frame toward the back plate.

Preferably, a positioning groove is provided on the outer frame to cooperate with each of the first magnetic strips, and the first magnetic strip is fixed within the corresponding positioning groove, so as to facilitate the provision of the first magnetic strip.

Preferably, a first magnetism isolating pad is provided on the outer frame to cooperate with each of the first magnetic strips, thereby preventing the generated magnetic field from affecting the outside components.

Preferably, the first magnetic strips are disposed evenly around the outer frame, thereby improving the uniformity of the force acting on the outer frame.

Preferably, the absorption member comprises a second magnetic strip for magnetically absorbing each of the first magnetic strips correspondingly, thereby enhancing the absorption force between the outer frame and the back plate.

### BRIEF DESCRIPTION OF THE DRAWINGS

FIG. 1 is a rear view of a display device in the prior art;

FIG. 2 is a schematic exploded view of a display device according to an embodiment of the present invention;

FIG. 3 is a partial enlarged view at a mark A of FIG. 2;

FIG. 4 is a structure view showing an arrangement of a first magnetic strip on an outer frame of the display device according to the embodiment of the present invention;

FIG. 5 is a schematic view showing a structure of an absorption member provided on the back plate according to the embodiment of the present invention; and

FIG. 6 is a rear view of the display device according to the embodiment of the present invention.

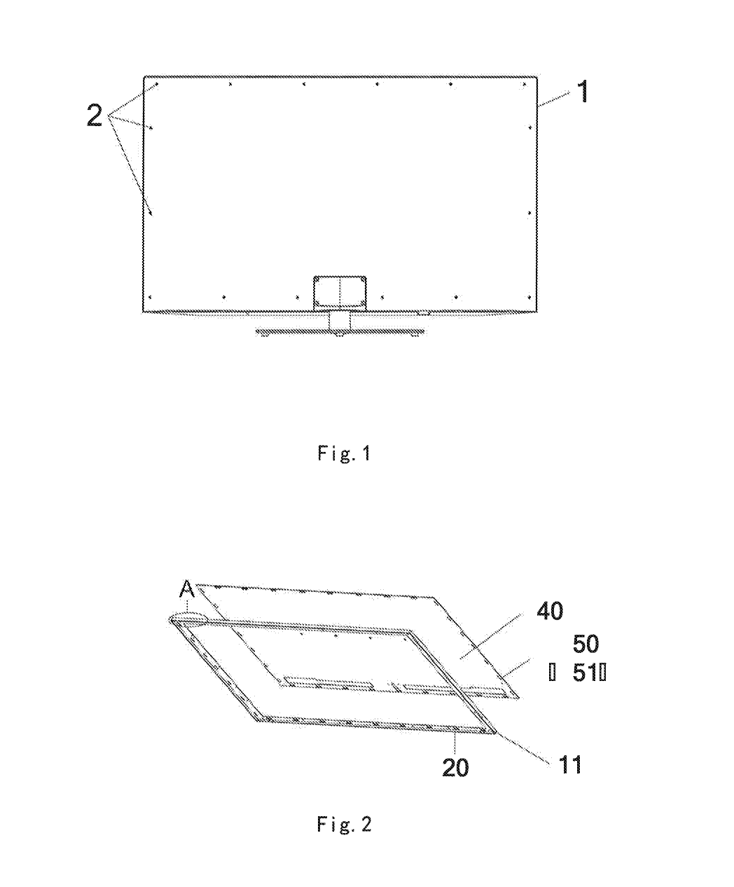

Explanation of reference numbers:

| | | |
|---|---|---|
| 1-outer frame | 2-screw | 10-display device |
| 11-outer frame | 12- positioning step structure | 13-positioning groove |
| 20-first magnetic strip | 30-first magnetism | 40-back plate |
| | isolating pad | |
| 50-absortpion member | 51-second magnetic strip | |

### DETAILED DESCRIPTION OF PREFERRED EMBODIMENTS OF THE INVENTION

In order to improve installing efficiency of the above display device, an embodiment of the present invention provides a display device. In the technical solution of the present invention, because the back plate and the outer frame are fixed and connected by magnetic absorption, it is easy to install the display device. In order that the objective, technical solutions and advantages of the present invention become clearer, the present disclosure is explained in detail below, taking non-limiting embodiments as an example.

FIG. 2 shows a schematic exploded view of a display device according to one embodiment of the present invention; and FIG. 6 shows a rear view of the display device as shown in FIG. 2 after being assembled. As shown in FIGS. 2 and 6, the display device according to the embodiment of the present invention includes a back plate 40 and an outer frame 11 disposed around the back plate 40. The outer frame 11 and the back plate 40 of the display device are respectively provided with a magnetic member and an absorption member for magnetically absorbing the corresponding magnetic member. The outer frame 11 and the back plate 40 are fixedly connected by means of the magnetic absorption between the magnetic member and the absorption member.

In the above embodiment, since the structure which is connected by the magnetic absorption is located between the outer frame 11 and the back plate 40, it facilitates the installation of the outer frame 11. Specifically, upon installing, the magnetic absorption between the outer frame 11 and the back plate 40 can fixedly connect the outer frame 11 with the back plate 40 rapidly, thereby finishing the installation of the entire display device 10. This facilitates the installation of the entire display device 10, meanwhile, the display device 10 becomes neat and decent on appearance.

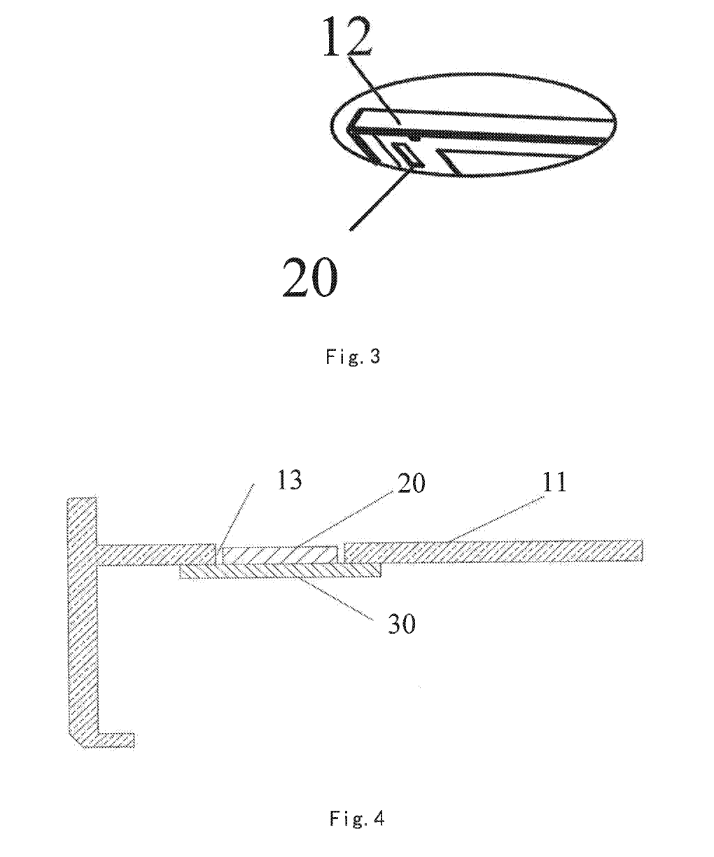

As shown in FIGS. 2 and 3, FIG. 3 is a partial enlarged view at a mark A of FIG. 2. Specifically, a positioning step structure 12 is provided on the outer frame 11, to cooperate with the back plate 40. Therefore, it can ensure the accurate positioning between the outer frame 11 and the back plate 40, when the connection is made by the magnetic absorption. Specifically, the positioning step structure 12 on the outer frame 11 surrounds the outer frame 11 so as to form a space for accommodating the back plate 40. In the specific installation, the back plate 40 is fixed within the accommodating space so that the outer frame 11 and the back plate 40 are positioned with respect to each other.

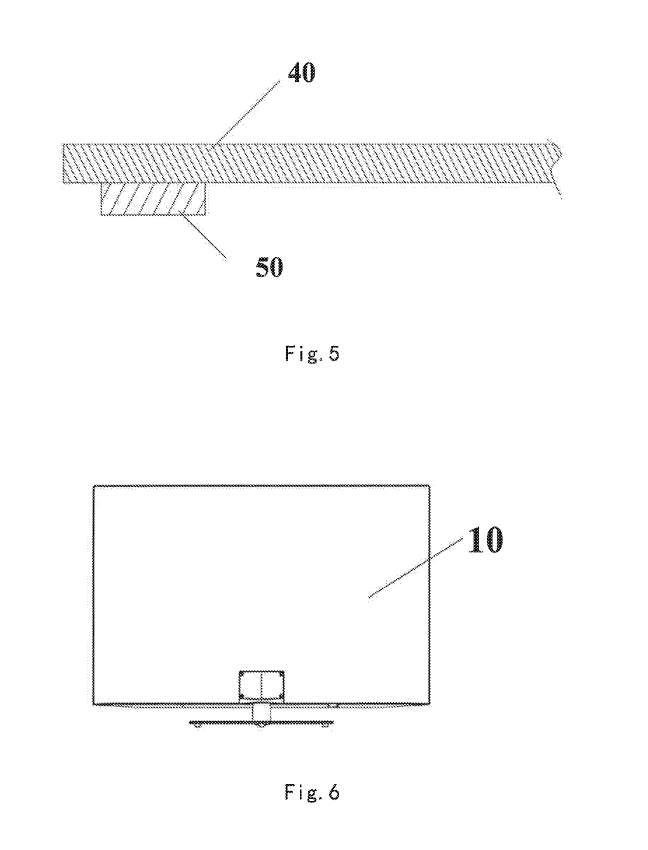

Specifically, the above magnetic member includes a plurality of first magnetic strips 20. When the magnetic connecting is adopted between the outer frame 11 and the back plate 40, the specific structure can have different structural arrangement. For example, the magnetic member is provided on one side of the outer frame 11 toward the back plate 40, and the absorption member is provided on one side of the back plate 40 toward the outer frame 11; or the magnetic member is provided on one side of the back plate 40 toward the outer frame 11, and the absorption member is provided on one side of the outer frame 11 toward the back plate 40. Preferably, as shown in FIGS. 2, 4 and 5, the first magnetic strips 20 are provided on the outer frame 11. When using the above structure, more preferably, the first magnetic strips 20 are evenly spaced apart around the outer frame 11, thereby ensuring that the force acting on the entire outer frame 11 is relatively even, while also improving the stability of the entire outer frame 11 when the entire outer frame 11 is absorbed onto the back plate 40.

As shown in FIG. 4, specifically, when the first magnetic strips 20 are installed, the outer frame 11 is provided with a positioning groove 13 to cooperate with each of the first magnetic strips 20. The first magnetic strip 20 is fixed within the positioning groove 13, thereby reducing the interior space of the outer frame 11 where the first magnetic strips 20 occupy, and preventing the installed first magnetic strips 20 from affecting other components.

Specifically, when the outer frame 11 employs the plurality of first magnetic strips 20, any adjacent two first magnetic strips 20 among the plurality of first magnetic strips 20 have opposite polarities in the direction toward the back plate 40, thereby preventing too large magnetic force in the generated magnetic field at the same side, and interfering the normal operation of the interior electrical devices within the display device 10.

In addition, in order to prevent the magnetic field of the first magnetic strips 20 installed on the outer frame 11 dissipating towards outside of the display device 10, preferably, the outer frame 11 is provided with a first magnetism isolating pad 30 thereon to cooperate with each of the first magnetic strips 20. Such first magnetism isolating pad 30 is provided on the side of the first magnetic strip 20 facing away from the back plate 40. Specifically, when the first magnetic strip 20 is fixed within the positioning groove 13, the first magnetism isolating pad 30 is provided at bottom of the positioning groove 13.

In addition, the absorption member 50 provided on the back plate 40 can have different structures, as long as it can absorb the first magnetic strip, for example, iron or magnet. In an embodiment, each absorption member 50 can be disposed as an iron strip or a magnetic strip. Preferably, the absorption member 50 includes second magnetic strips 51 for magnetically absorbing each of the first magnetic strips 20 correspondingly. At this time, a pair of the ferromagnet or magnetic strips facing to each other between the outer frame 11 and the back plate 40 has opposite polarities at opposite ends thereof. For example, in the pair of the magnetic strips, the end of the first magnetic strip 20 provided on the outer frame 11 toward the back plate 40 is a N pole, whereas the end of the second magnetic strip 51 toward the outer frame 11 which is provided on the back plate 40 and for magnetically absorbing the first magnetic strip 20 is a S pole.

Of course, furthermore, a positioning groove (not shown, similar to the above positioning groove 13) is provided on the back plate 40, to cooperate with each of the second magnetic strips 51. The second magnetic strip 51 is fixed within the corresponding positioning groove. Also, second magnetism isolating pads are provided between the absorption member 50 on the back plate 40 and the back plate 40, thereby reducing the magnetic influence of the entire magnetic absorption device to other components.

In the above embodiment, it shows the structure that the magnetic strip is provided on the outer frame 11 and the absorption member 50 is provided on the back plate 40. It should be understood that the display device 10 provided by the present disclosure is not limited to the above specific example, but also can employ other structures, such as the absorption member 50 is provided on the outer frame 11 and the magnetic strip is provided on the back plate 40. Because the principle in this case is the same as that explained in the above embodiment (that is, by directly replacing the absorption member 50 and the magnetic member 20), it is not repeatedly discussed in detail.

Apparently, the person skilled in the art can make various changes and modifications to the present invention, without departing from the spirit and scope of the present invention. As such, any changes, equivalent replacement, modification within the spirit and principles of the disclosure can be made by those skilled in the art and should fall into the scope of the present invention.

1. A display device, comprising a back plate and an outer frame disposed around the back plate, wherein
one of the outer frame and the back plate is provided with a magnetic member and the other is provided with an absorption member for magnetically absorbing the corresponding magnetic member, and
the outer frame and the back plate are fixedly connected by the magnetic absorption between the magnetic member and the absorption member.

2. The display device as claimed in claim 1, wherein the magnetic member is provided on the side of the outer frame toward the back plate and the absorption member is provided on the side of the back plate toward the outer frame.

3. The display device as claimed in claim 1, wherein the magnetic member is provided on the side of the back plate toward the outer frame and the absorption member is provided on the side of the outer frame toward the back plate.

4. The display device as claimed in claim 2, wherein the magnetic member comprises a plurality of first magnetic strips evenly arranged around the outer frame.

5. The display device as claimed in claim 4, wherein any two adjacent first magnetic strips of the plurality of first magnetic strips have opposite polarities in the direction towards the back plate.

6. The display device as claimed in claim 4, wherein a positioning groove is provided on the outer frame to cooperate with each of the first magnetic strips, and the first magnetic strip is fixed within the corresponding positioning groove.

7. The display device as claimed in claim 4, wherein a first magnetism isolating pad is provided on the outer frame to cooperate with each of the first magnetic strips.

8. The display device as claimed in claim 4, wherein the absorption member comprises a second magnetic strip for magnetically absorbing each of the first magnetic strips correspondingly.

9. The display device as claimed in claim 8, wherein a positioning groove is provided on the back plate to cooperate with each of the second magnetic strips, and the second magnetic strip is fixed within the corresponding positioning groove.

10. The display device as claimed in claim 8, wherein a second magnetism isolating pad is provided between the back plate and the corresponding second magnetic strip, for cooperating with each of the second magnetic strips.

11. The display device as claimed in claim 3, wherein the magnetic member comprises a plurality of first magnetic strips evenly arranged around the back plate.

12. The display device as claimed in claim 11, wherein a positioning groove is provided on the back plate to cooperate with each of the first magnetic strips, and the first magnetic strip is fixed within the corresponding positioning groove.

13. The display device as claimed in claim 11, wherein any two adjacent first magnetic strips of the plurality of first magnetic strips have opposite polarities in the direction towards the outer frame.

14. The display device as claimed in claim 11, wherein a first magnetism isolating pad is provided between the back plate and the first magnetic strip to cooperate with each of the first magnetic strips.

15. The display device as claimed in claim 11, wherein the absorption member comprises a second magnetic strip for magnetically absorbing each of the first magnetic strips correspondingly.

16. The display device as claimed in claim 15, wherein a positioning groove is provided on the outer frame to cooperate with each of the second magnetic strips, and the second magnetic strip is fixed within the corresponding positioning groove.

17. The display device as claimed in claim 15, wherein a second magnetism isolating pad is provided on the outer frame to cooperate with each of the second magnetic strips.

18. The display device as claimed in claim 8, wherein opposed ends of a pair of the magnetic strips consisting of the first magnetic strip and the second magnetic strip which are disposed on the outer frame and the back plate facing to each other have opposite polarities.

19. The display device as claimed in claim 1, wherein a positioning step structure is provided on the outer frame to cooperate with the back plate.

20. The display device as claimed in claim 1, wherein the absorption member comprises iron strips for magnetically absorbing the magnetic member.
